(19) United States
(12) Patent Application Publication
(10) Pub. No.: US 2025/0203768 A1
(43) Pub. Date: Jun. 19, 2025

(54) CERAMIC WIRING BOARD, ELECTRONIC DEVICE, AND ELECTRONIC MODULE

(71) Applicant: KYOCERA Corporation, Kyoto-shi, Kyoto (JP)

(72) Inventor: Makoto YAMAMOTO, Kirishima-shi (JP)

(73) Assignee: KYOCERA Corporation, Kyoto-shi, Kyoto (JP)

(21) Appl. No.: 18/837,927

(22) PCT Filed: Feb. 22, 2023
(86) PCT No.: PCT/JP2023/006541

§ 371 Date: Mar. 4, 2025

(30) Foreign Application Priority Data
Feb. 28, 2022 (JP) 2022-028853

(51) Int. Cl. H05K 1/03; H05K 1/09; H05K 1/18

(52) U.S. Cl. CPC H05K 1/0306; H05K 1/092; H05K 1/181; H05K 2201/0242; H05K 2201/0266; H05K 2201/0269; H05K 2201/1006; H05K 2201/10075

(57) ABSTRACT

To provide a ceramic wiring board that may be thin, but have higher toughness, and have high connection strength to a wiring, an electronic device, and an electronic module. A ceramic wiring board (21) includes a ceramic sinter (211) containing an alumina crystal phase and a zirconia crystal phase as main components and containing manganese oxide and silica as auxiliary components, and a wiring (212) positioned in at least one of a surface or an inside of the ceramic sinter (211) and containing molybdenum as a main component. The zirconia crystal phase includes first crystal grains (211a) and second crystal grains (211b) having a larger grain size than the first crystal grains (211a), and the second crystal grains (211b) positioned at an interface between the ceramic sinter (211) and the wiring (212) include the second crystal grains entering a recess of the wiring (212).

### TECHNICAL FIELD

The present disclosure relates to a ceramic wiring board, an electronic device, and an electronic module.

### BACKGROUND OF INVENTION

A ceramic wiring board on which an electronic component is mounted is described in International Publication No. 2012/060341 as follows. A ceramic material contains alumina as a main component. The alumina contains partially stabilized zirconia and a ratio of tetragonal crystals within crystals of the partially stabilized zirconia is increased. This provides a ceramic substrate having high flexural strength without an increase in the dielectric constant. A metallization layer serving as a metallic wiring contains a glass component. This provides a wiring board having high bonding strength between the ceramic substrate and the metallic wiring.

### SUMMARY

### Solution to Problem

In an aspect of the present disclosure, a ceramic wiring board includes a ceramic sinter and a wiring. The ceramic sinter contains an alumina crystal phase and a zirconia crystal phase as main components and contains manganese oxide and silica as auxiliary components. The wiring is positioned in at least one of a surface or an inside of the ceramic sinter and contains molybdenum as a main component. The zirconia crystal phase includes first crystal grains and second crystal grains having a larger grain size than the first crystal grains. The second crystal grains positioned at an interface between the ceramic sinter and the wiring include the second crystal grains entering a recess of the wiring.

### BRIEF DESCRIPTION OF THE DRAWINGS

FIG. 1A is a sectional view illustrating a schematic configuration of an electronic module.

FIG. 1B is a sectional view illustrating a schematic configuration of the electronic module.

FIG. 1C is a sectional view illustrating a schematic configuration of the electronic module.

FIG. 2 is a photograph of an example of a section of a ceramic wiring board.

FIG. 3 is an enlarged view of the section of the ceramic wiring board.

FIG. 4A illustrates distribution of zirconia in a section of a sintered ceramic wiring board.

FIG. 4B illustrates distribution of manganese in the section of the sintered ceramic wiring board.

FIG. 4C illustrates distribution of silica in the section of the sintered ceramic wiring board.

### DESCRIPTION OF EMBODIMENTS

Hereinafter, embodiments will be described on the basis of the drawings.

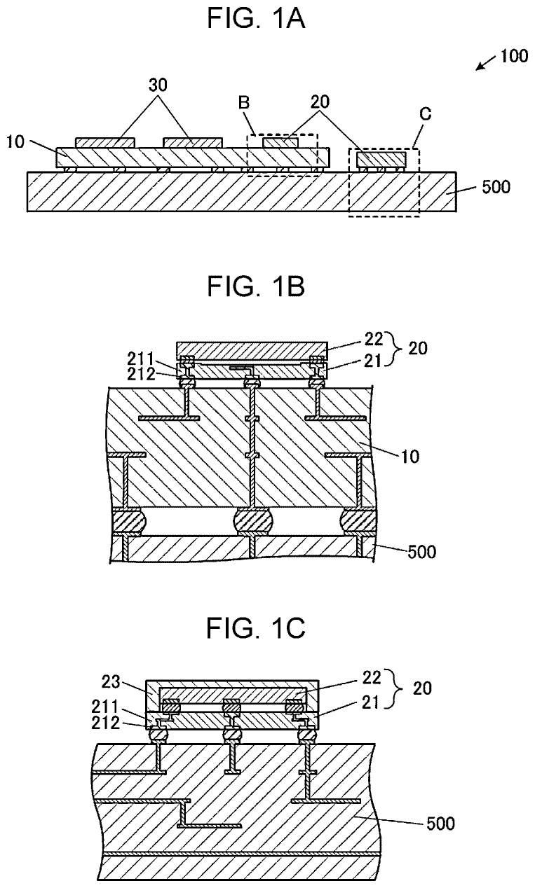

FIG. 1A to FIG. 1C are sectional views illustrating schematic configurations of an electronic module 100 of an embodiment. FIG. 1B is an enlarged view of portion B in FIG. 1A. FIG. 1C is an enlarged view of portion C in FIG. 1A.

As illustrated in FIG. 1A, the electronic module 100 includes, for example, a module substrate 10 mounted on an external main board 500 incorporated into an electronic apparatus or the like, and various electronic devices 20 mounted on the module substrate 10. Such an electronic device 20 is, for example, a SAW (Surface Acoustic Wave) filter or a quartz device, but is not particularly limited to these. The module substrate 10 and the electronic device 20 can constitute a function module related to a function. Examples of the function module include a front-end module related to a communication function. The electronic device 20 preferably has an appropriate size for constituting a function module and may be, in particular, a WLP (Wafer Level Package) that is thin in the height direction (direction perpendicular to a mount surface of the module substrate 10 for the electronic device 20). On the module substrate 10, in addition to the electronic device 20, electronic components 30 such as a switching element, a filter component, an antenna component, and a power amplifier may be mounted. The electronic device 20 and the electronic components 30 on the module substrate 10 may be covered and sealed with a lid member or a sealing resin.

As illustrated in FIG. 1B, the electronic device 20 includes a ceramic wiring board 21 and an electronic element 22 such as a SAW chip included in the SAW filter or a quartz oscillator included in the quartz device. The ceramic wiring board 21 includes a ceramic sinter 211 and a wiring 212 positioned in at least one of a surface or an inside of the ceramic sinter 211. The electronic element 22 is electrically connected to the ceramic wiring board 21 via a connection pad or the like. The connection pad is connected, via the wiring 212 positioned in the surface and the inside of the ceramic wiring board 21, to, for example, a connection pad of the module substrate 10. Electric power and signals are sent or received via this connection pad. The electronic element 22 may be formed together with the ceramic wiring board 21 as a single piece on a wafer by semiconductor processes. A wafer in which such electronic elements 22 are arranged in a matrix is placed on a wiring board for producing multiple wiring boards in which such ceramic wiring boards 21 are arranged in a matrix. The electronic elements 22 are each connected to a respective one of the ceramic wiring boards 21 and then cut and divided to provide a plurality of electronic devices 20.

As illustrated in FIG. 1A and FIG. 1C, the electronic device 20 may be mounted directly on the main board 500 without the module substrate 10 disposed therebetween. The electronic device 20 illustrated in FIG. 1B is of the WLP type while the electronic device 20 illustrated in FIG. 1C is of a CSP (Chip Size Package/Chip Scale Package) type. Also in such an electronic device 20, the electronic element 22 is electrically connected to the ceramic wiring board 21 via a connection pad or the like. The connection pad is connected, via the wiring 212 positioned in the surface and the inside of the ceramic wiring board 21, to a connection pad or the like of the main board 500. Electric power and signals are sent or received via the wiring 212 and the connection pad. As illustrated in FIG. 1C, the electronic element 22 on the ceramic wiring board 21 may be covered and sealed with a lid member or a sealing resin 23. The electronic component sealed with the resin can be obtained in the following manner. For example, such electronic elements 22 are mounted on the ceramic wiring boards 21 of a wiring board for producing multiple wiring boards. The plurality of electronic elements 22 are collectively sealed with the sealing resin and then cut and divided.

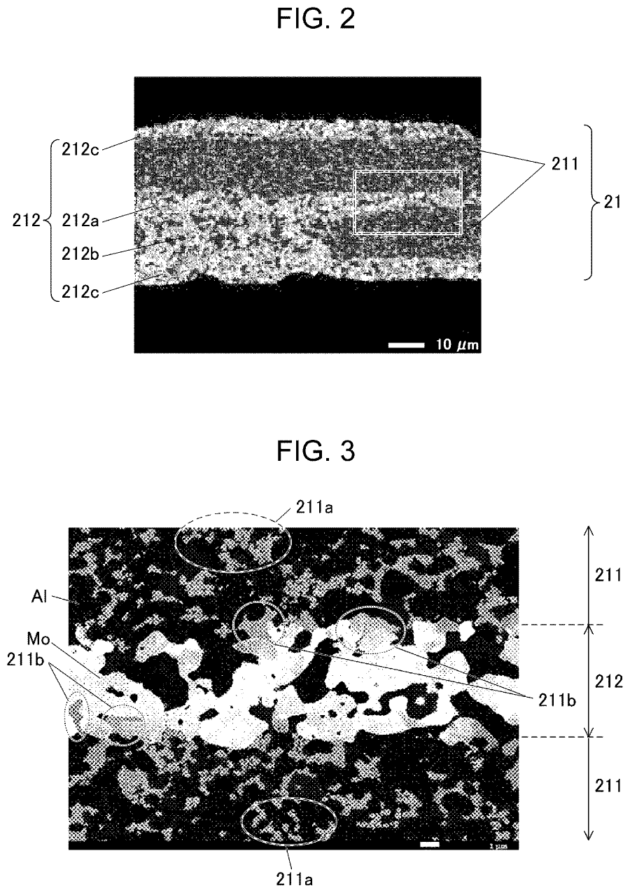

FIG. 2 is an example of a photograph of a section of the ceramic wiring board 21 captured using a SEM (Scanning Electron Microscope).

The ceramic wiring board 21 includes the ceramic sinter 211 (gray area) and the wiring 212 (white area). The ceramic sinter 211 is a ceramic insulating plate, but is not limited to a ceramic sinter having flat upper and lower surfaces or the like. The ceramic sinter 211 contains a crystal phase of alumina (aluminum oxide, Al₂O₃) and a crystal phase of zirconia (zircon oxide, ZrO₂) as main components (alumina-zirconia). The phrase “contains . . . as main components” means that the total content of alumina and zirconia is from 85 to 95 wt % of the whole. When the total content of alumina and zirconia is more than this range, the sinterability degrades. When the total content of alumina and zirconia is less than the range, the strength degrades. The content of zirconia is from 25 to 40 wt % of the whole and the content of alumina is from 50 to 70 wt % of the whole. When the content of zirconia in the main components is less than the range, the toughness degrades and cracking tends to occur in the case of a small thickness. When the content of zirconia is higher than the range, the relative dielectric constant increases. The zirconia may be partially stabilized with a stabilizer such as yttria (Y₂O₃). The ceramic sinter 211 contains, as auxiliary components, manganese oxide (Mn₂O₃) and silica (silicon dioxide, SiO₂). These are sintering agents for alumina and zirconia. In a non-limiting example, weight ratios (described in wt % and herein regarded as the same as mass ratios) are 55 wt % of alumina, 35 wt % of zirconia, 5 wt % of silica, 3 wt % of manganese oxide (Mn₂O₃), and 2 wt % of magnesium oxide (MgO). Thus, the ratio of zirconia may be more than 30 wt %. When the ratio of zirconia is more than 30 wt %, the ceramic wiring board 21 has high toughness and is less likely to crack even in the above-described case of being very thin.

The wiring 212 contains a conductive metal for transmitting signals, electric power, and the like and is positioned, in this case, in both surfaces (surfaces) and the inside of the ceramic sinter 211. An internal wiring 212a of the ceramic sinter 211 is connected, via a through-via 212b, to a surface wiring 212c (wiring in the lower surface in this case) of the ceramic wiring board 21. The wiring 212 contains, as a conductive component, molybdenum (Mo) as a main component and contains, as a non-conductive other component, alumina. The wiring 212 does not contain tungsten (W) as a main component. This provides a decrease in the sintering temperature, compared with the related art.

The ceramic wiring board 21 has a thickness of not more than 100 μm, for example, from about 50 to about 100 μm, and more preferably less than 75 μm, for example, about 50 μm. The internal wiring 212a and the surface wiring 212c have a thickness of not more than 20 μm, for example, from about 5 to about 10 μm. The through-via 212b has a diameter of not more than 100 μm, for example, from about 50 to about 90 μm. In this case, the thickness of the wiring 212 is not negligible relative to the thickness of the ceramic sinter 211.

The ceramic wiring board 21 including such a combination of the ceramic sinter 211 and the wiring 212 can be obtained by subjecting a powder material of a ceramic material that is to form a ceramic layer and a metallization member that is to form a wiring to molding using a mold or the like and then to collective sintering. The ceramic wiring board 21 can be produced in the following manner, for example. First, the powder material of the ceramic material, a binder, and a solvent are kneaded to prepare slurry. This slurry is formed into a sheet shape by a forming process such as a doctor blade process to obtain a green sheet that is to serve as the ceramic layer. The ceramic material contains the above-described alumina (for example, 55 wt %), zirconia (35 wt %), silica (5 wt %), manganese oxide (3 wt %), and magnesium oxide (2 wt %).

Subsequently, on the obtained green sheet, a conductive paste that is to form the metallization member is used to form a wiring pattern. A through-hole is formed at a predetermined position of the green sheet using a die or the like. The conductive paste is filled into the through-hole, to form a via conductor pattern that is to serve as the through-via 212b. At predetermined positions of the green sheet in which the via conductor pattern is formed, predetermined patterns are printed with the conductive paste, to prepare a green sheet in which wiring patterns of the internal wiring 212a and the surface wiring 212c are formed. A plurality of such green sheets in which the wiring patterns are formed are laminated to prepare a laminate. This laminate is fired to provide the ceramic wiring board 21 in which the ceramic sinter 211 and the wiring 212 are formed by co-firing.

The metallization member contains molybdenum as a conductive component. Molybdenum is a metal that tends to be sintered at a low temperature, compared with tungsten. The conductive component employed is molybdenum alone, so that sintering can be performed at a temperature at which the grain size of the ceramic material described later is not considerably changed by sintering. For example, the molybdenum has an average grain size of 2.5 μm. The metallization member to be fired does not contain glass materials, in particular, silica. Such sintering agents are not contained, so that sintering of molybdenum grains does not proceed at lower temperatures. Thus, the timing of sintering shrinkage of the metallization member does not deviate from that of the ceramic material, and the probability of separation or the like is reduced.

The metallization member may contain, in addition to molybdenum serving as the main component, alumina. Alumina-zirconia has a thermal expansion coefficient of about 8 ppm/° C. while molybdenum has a thermal expansion coefficient of about 5 ppm/° C. Thus, a sintering process ordinarily performed causes bend or the like due to the difference between the thermal expansion coefficients. As described above, the thickness of the wiring 212 is not negligible relative to the ceramic sinter 211 and hence this bend tends to be large. Thus, the ceramic sinter 211 and the wiring 212 tend to separate from each other during subsequent cooling or the like. When the wiring 212 contains alumina, the wiring 212 can have a thermal expansion coefficient close to the thermal expansion coefficient of the ceramic sinter 211, and hence the probability of separation of the ceramic sinter 211 and the wiring 212 from each other can be reduced. The thermal expansion coefficient of the wiring 212 alone may be adjusted with zirconia; however, when zirconia having a lower sintering temperature than alumina is contained, sintering of molybdenum grains may proceed at lower temperatures. In order to match the timing of sintering shrinkage with that of the ceramic material, the wiring 212 preferably contains alumina. The alumina has an average grain size of 1.5 μm, for example. The alumina contained facilitates, as described later, migration of silica and manganese to the metallization layer. The metallization member may contain molybdenum serving as the main component in an amount of from 70 to 97 wt % and alumina in an amount of from 3 to 30 wt %. When the content of alumina is in this range, the probability of separation of the wiring is reduced and an increase in the electric resistance is suppressed.

When, as the sintering agents for zirconia, manganese oxide and silica are contained as described above, particularly compared with a case of not containing manganese oxide, the combination of zirconia, silica, and manganese causes a decrease in the sintering temperature and sintering in this case is performed at about 1400° C., for example. In the ceramic sinter 211, as the grain sizes of the alumina crystal phase and the zirconia crystal phase increase, the toughness (flexural strength) of the ceramic sinter 211 is known to degrade. In the powder material included in the ceramic material, the grain sizes are small relative to the metallization member (for example, the alumina has an average grain size of 0.5 μm and the zirconia has an average grain size of 0.2 μm). The sintering temperature and the sintering time are ordinarily determined such that sintering does not considerably change these sizes (for example, in a range of from 1.0 to 2.5 times the original grain sizes. the grain sizes of the first crystal grains).

At the sintering temperature, the intermediate reaction product between silica and manganese turns into a liquid phase and easily migrates. In particular, as described above, the metallization member does not contain silica, so that silica and manganese tend to migrate to the metallization member side due to the large concentration gradient of silica between the ceramic material and the metallization member. In particular, the wiring 212 contains alumina to thereby facilitate the migration. Specifically, in addition to the concentration gradients of silica and manganese, alumina that easily reacts with these is contained in the metallization member, so that the migration to the metallization member is further facilitated.

FIG. 3 is an enlarged view of a portion surrounded by the alternate long and short dash line in the section of the ceramic wiring board 21 in FIG. 2.

As described above, the white area corresponds to molybdenum of the wiring 212. The black area corresponds to alumina (described here as Al) contained in both of the ceramic sinter 211 and the wiring 212. The gray area corresponds to zirconia.

Zirconia crystals have grown in the molybdenum surface (interface) positioned near the interface between the ceramic sinter 211 and the wiring 212, in particular, in recesses (for example, second crystal grains 211b in portions marked with dotted lines), compared with the related art (portions other than the interface. for example, first crystal grains 211a in portions marked with dashed lines in FIG. 3). Specifically, the first crystal grains 211a of zirconia ordinarily observed in the inside of the ceramic sinter 211 have grain sizes the same as and/or similar to those of the crystal grains of zirconia in the original ceramic material. By contrast, the second crystal grains 211b positioned along (molybdenum of) the wiring 212, entering and reaching deeply the recesses of the wiring 212 (in particular, connecting the outside and the inside of the recesses) have grown considerably as a whole, compared with the sizes of the crystal grains in the original ceramic material (first crystal grains 211a).

As described above, the original crystal grains of zirconia have an average grain size of about 0.2 μm. In the inside of the ceramic sinter 211 (regions apart from the interface with the wiring 212), the size does not considerably change (remains the same and/or similar. substantially not more than 0.5 μm). By contrast, in the region (interface) in contact with molybdenum of the wiring 212, zirconia grains have grown to not less than 1.0 μm (grain sizes larger than those of the first crystal grains 211a), for example, from about 2.0 to about 3.0 μm. Note that not all the zirconia crystals in contact with molybdenum (positioned at the interface) necessarily have grown to the sizes. Conversely, even in the inside of the ceramic sinter 211 apart from the interface, zirconia crystals having grown in accordance with, for example, the distribution of silica and manganese may be present. As a whole, there is the following tendency. The inside of the ceramic sinter 211 apart from the interface has a low ratio of zirconia crystals having large grain sizes (second crystal grains 211b) while the near-interface region (region in contact with the interface) has a high ratio of zirconia crystals (second crystal grains 211b) having larger grain sizes than in the inside of the ceramic sinter 211 (positions apart from the interface).

The migration of silica and manganese results in generation of a three-component liquid phase of zirconia grains positioned at the boundary (interface) with the metallization layer, and silica and manganese having migrated. This facilitates sintering of the zirconia grains positioned at the interface to grow the grains, to form the second crystal grains 211b having large grain sizes. Zirconia and silica alone do not achieve generation of a liquid phase at a low temperature. Addition of manganese facilitates sintering and grain growth of zirconia grains at a low temperature. In the process of the grain growth, the second crystal grains 211b of the zirconia crystal phase enter recesses in the fine irregular surfaces of molybdenum of the metallization layer. The generation of the second crystal grains 211b due to zirconia, silica, and manganese can occur at positions apart from the interface. However, migration of silica and manganese to the metallization member results in a larger amount of the intermediate product of silica and manganese at the interface between the metallization member and the ceramic material than in positions apart from the interface. Thus, zirconia grains positioned at the interface are sintered more rapidly than zirconia at the positions apart from the interface. As a result, the crystal grain sizes tend to locally increase, so that the ratio of the second crystal grains 211b positioned at the interface is higher than the ratio of the second crystal grains 211b positioned apart from the interface. Thus, the grown zirconia crystals (second crystal grains 211b) function as wedges for the molybdenum, so that the wiring 212 is less likely to separate from the ceramic sinter 211. The wedges are zirconia crystal grains having high toughness and hence provide high bonding strength, compared with the case of using a glass component to bond together the wiring 212 and the ceramic sinter 211. On the other hand, as described above, sintering is performed such that ordinary zirconia grains positioned apart from the interface do not grow to large sizes, so that the toughness of the ceramic sinter 211 as a whole does not degrade. Alumina is contained in both of the ceramic material and the metallization member, to facilitate bonding between the ceramic material and the metallization member caused by sintering and to simultaneously facilitate sintering and bonding between others, zirconia and molybdenum.

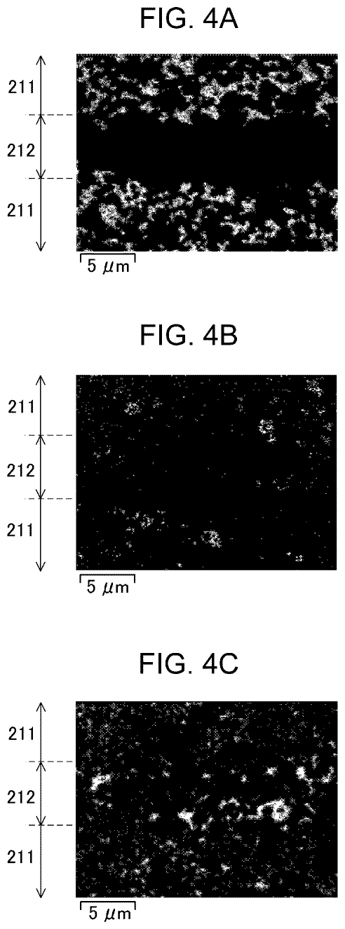

FIG. 4A to FIG. 4C are photographs of distributions of zirconia, manganese, and silica components in the section of the sintered ceramic wiring board 21 in FIG. 3.

As illustrated in FIG. 4A, the zirconia component does not enter the inside of the wiring 212 and is distributed only in the regions of the ceramic sinter 211 positioned up and down of the drawing. Note that, in the photograph, crystal grains having small sizes are not separated from each other and areas in which zirconia crystals having small grain sizes join together are collectively indicated as regions where zirconia is distributed.

On the other hand, as illustrated in FIG. 4B, after sintering, manganese not contained in the original metallization member slightly enters the wiring 212. In addition, as illustrated in FIG. 4C, after sintering, a large amount of silica entering the interface with the wiring 212 and the inside of the wiring 212 is observed. Thus, as described above, the silica and manganese components having turned into a liquid phase migrate, in accordance with the concentration gradient of silica, from the ceramic sinter 211 to the wiring 212.

As described above, the silica and manganese components that turn into a liquid phase at a low temperature migrate to the metallization member (wiring 212), to facilitate sintering of zirconia positioned in the near-boundary regions between the metallization member and the ceramic material (near-interface regions between the wiring 212 and the ceramic sinter 211). Zirconia grows as grains in the near-interface regions and hence is kept in recesses of molybdenum in the near-interface regions and sintered into crystals. Thus, a portion of zirconia grows to crystals having large sizes that fill the recesses of molybdenum. Thus, the presence of large crystal grains of zirconia is localized mainly in the near-interface regions. Such large crystal grains fit into the recesses of molybdenum, so that the zirconia crystal grains function as wedges to improve the bonding between the wiring 212 and the ceramic sinter 211. Thus, the wiring 212 and the ceramic sinter 211 become less likely to be separated. On the other hand, zirconia positioned apart from the wiring 212 is less likely to come into contact with silica and manganese and, without facilitation of sintering, forms crystals having sizes the same as and/or similar to those of the related art. This suppresses a decrease in the toughness of the ceramic sinter 211 due to an increase in the crystal grain sizes.

As has been described so far, the ceramic wiring board 21 of the embodiment includes the ceramic sinter 211 containing an alumina crystal phase and a zirconia crystal phase as main components and containing manganese oxide and silica as auxiliary components, and the wiring 212 positioned in at least one of the surface or the inside of the ceramic sinter 211 and containing molybdenum as a main component. The zirconia crystal phase includes the first crystal grains 211a and the second crystal grains 211b having a larger grain size than the first crystal grains 211a. The second crystal grains 211b include the second crystal grains 211b positioned at the interface between the ceramic sinter 211 and the wiring 212 and entering the recesses of the wiring 212. The first crystal grains 211a herein refer to, in the ceramic sinter 211, crystal grains that have not grown to large crystal grain sizes relative to those of the ceramic material serving as the raw material, and have grain sizes of less than 1.0 μm and, in general, as described above, not more than 0.5 μm.

As described above, in the ceramic wiring board 21 having the zirconia crystal phase distribution unique to the present disclosure, zirconia having small grain sizes in the inside of the ceramic sinter 211 improves the toughness (flexural strength) of the ceramic wiring board 21. On the other hand, zirconia positioned at the interface with the molybdenum of the wiring 212, entering recesses of the molybdenum, and having grown to large grain sizes suppresses separation of the wiring 212. Thus, the ceramic wiring board 21 that, even in the case of being thin, has higher toughness, and has high connection strength between the wiring 212 and the ceramic sinter 211 can be obtained. In particular, even in the case of the ceramic wiring board 21 that is thin, a decrease in the yield due to, for example, damage or separation of the wiring 212 caused by the difference in the thermal expansion coefficients between the ceramic sinter 211 and the wiring 212 can be suppressed.

The ratio of the second crystal grains 211b positioned at the interface is higher than the ratio of the second crystal grains 211b positioned apart from the interface. Thus, the second crystal grains 211b having large grain sizes are not necessarily formed at the interface alone and all the zirconia crystals at the interface do not necessarily grow to large grain sizes; however, as a whole, the zirconia crystals at the interface tend to grow larger. Such growth of zirconia crystals can be caused easily without highly strict control of sintering conditions and at costs of the related art, to provide the ceramic wiring board 21 having high toughness and high connection strength between the wiring 212 and the ceramic sinter 211.

The second crystal grains 211b include a portion having a shape conforming to the molybdenum irregularity of the wiring 212. The second crystal grains 211b grow particularly along the irregularity of the molybdenum surface, and hence tend to bond to molybdenum with more certainty, to provide bonding strength between the wiring 212 and the ceramic sinter 211.

The wiring 212 contains alumina. This facilitates migration of the auxiliary components in the ceramic material to the wiring 212 during sintering, and facilitates, during sintering of the ceramic material and the metallization member, crystal growth and bonding of zirconia along the surface of molybdenum.

The electronic device 20 of an embodiment includes the above-described ceramic wiring board 21 and the electronic element 22 mounted on the ceramic wiring board 21. The electronic module 100 of an embodiment includes the electronic device 20 and the module substrate 10 on which the electronic device 20 is mounted. The ceramic wiring board 21 of the embodiment is used for such an electronic device 20, to provide an electronic device and an electronic module in which more various electronic elements are mounted on the thinner substrate. In addition, elements related to functions can be provided as small packages.

Note that the above-described embodiments are examples and can be changed in various ways.

For example, the wiring 212 may not be positioned in the inside of the ceramic sinter 211 or may be positioned in the inside alone. When the wiring 212 is positioned in a surface of the ceramic sinter 211, the wiring 212 may be positioned in one of the surfaces of the ceramic sinter 211 alone. The wiring used herein may include wide-ranging conductor surfaces such as a ground plane.

In the embodiment described above, the zirconia crystal phase on the interface has been described as having grown along the recesses in the surfaces of molybdenum crystals; however, the zirconia crystal phase may not be in contact with a portion of the recesses. Conversely, in some recesses of molybdenum, zirconia crystals may not grow in contact with the recesses.

The shape of the ceramic wiring board 21 is not particularly limited. The ceramic wiring board 21 includes at least, in the inside or in the surface, the wiring 212. The ceramic wiring board 21 may include a recess containing the electronic element 22.

The metallization member does not necessarily contain alumina. In addition, for the ceramic material and the metallization member, components that are not clearly described above as being contained or not being contained may be appropriately added.

Other specific details of the above-described features, structures, components, ratios of the components, procedures of the production method, and the like in the embodiments can be appropriately changed without departing from the spirit and scope of the present disclosure. Some embodiments have been described; however, the scope of the present invention is not limited to the above-described embodiments and include the scope of the invention described in Claims and range of equivalents to the invention.

### INDUSTRIAL APPLICABILITY

The present disclosure is applicable to ceramic wiring boards, electronic devices, and electronic modules.

1. A ceramic wiring board comprising:
a ceramic sinter containing an alumina crystal phase and a zirconia crystal phase as main components and containing manganese oxide and silica as auxiliary components; and
a wiring positioned in at least one of a surface or an inside of the ceramic sinter and containing molybdenum as a main component,
wherein the zirconia crystal phase includes first crystal grains and second crystal grains having a larger grain size than the first crystal grains, and the second crystal grains positioned at an interface between the ceramic sinter and the wiring include the second crystal grains entering a recess of the wiring.

2. The ceramic wiring board according to claim 1, wherein a ratio of the second crystal grains positioned at the interface is higher than a ratio of the second crystal grains positioned apart from the interface.

3. The ceramic wiring board according to claim 1- or 2, wherein the second crystal grains include a portion having a shape conforming to an irregularity of molybdenum of the wiring.

4. The ceramic wiring board according to claim 1, wherein the wiring contains alumina.

5. An electronic device comprising:
the ceramic wiring board according to claim 1; and
an electronic element mounted on the ceramic wiring board.

6. An electronic module comprising:
the electronic device according to claim 5; and
a module substrate on which the electronic device is mounted.
